(19) United States
(12) Patent Application Publication
(10) Pub. No.: US 2018/0247962 A1
(43) Pub. Date: Aug. 30, 2018

(54) IMAGE SENSOR PACKAGE STRUCTURE AND PACKAGING METHOD THEREOF

(71) Applicant: China Wafer Level CSP Co., Ltd., Suzhou, Jiangsu (CN)

(72) Inventors: Zhiqi Wang, Suzhou, Jiangsu Province (CN); Zhijie Shen, Jiangsu (CN); Jiawei Chen, Jiangsu (CN)

(73) Assignee: China Wafer Level CSP Co., Ltd., Suzhou, Jiangsu (CN)

(21) Appl. No.: 15/753,968

(22) PCT Filed: Aug. 25, 2016
(86) PCT No.: PCT/CN2016/096737

§ 371 Date: Feb. 20, 2018

(30) Foreign Application Priority Data
Aug. 28, 2015 (CN) 201510540994.0
Aug. 28, 2015 (CN) 201520662836.8

(51) Int. Cl. H01L 27/146

(52) U.S. Cl. CPC H01L 27/14618; H01L 27/14683; H01L 27/14636; H01L 27/14627

(57) ABSTRACT

Provided are an image sensor packaging structure and a packaging method thereof. The package structure includes a chip to be packaged and a substrate. The chip includes a first surface and a second surface respectively located on two sides of the chip, where the first surface is provided with a photosensitive region and a first contact pad located around the photosensitive region. The substrate is arranged at the side of the first surface of the chip, where the substrate includes a third surface and a fourth surface respectively provided on two sides of the substrate, and the third surface is provided with a second contact pad and a third contact pad. The second contact pad is located at a side of the third contact pad facing away from the photosensitive region.

This application claims priority to Chinese Patent Application No. 201510540994.0, titled “IMAGE SENSOR PACKAGE STRUCTURE AND PACKAGING METHOD THEREOF”, filed with the Chinese State Intellectual Property Office on Aug. 28, 2015, and Chinese Patent Application No. 201520662836.8, titled “IMAGE SENSOR PACKAGE STRUCTURE”, filed with the Chinese State Intellectual Property Office on Aug. 28, 2015, both of which are incorporated herein by reference in their entireties.

### FIELD

The present disclosure relates to the technical field of semiconductor chip packaging, and in particular to an image sensor packaging structure and a packaging method thereof.

### BACKGROUND

In the conventional image sensor packaging structure, the image sensor is generally packaged by wire bonding. With the rapid development of the integrated circuit, the size of the product cannot meet an ideal requirement due to a long wire. With the development of the technology, the wafer level packaging gradually replaces the wire bonding packaging, and the wafer level packaging is a more commonly-used packaging method at present.

The conventional wafer level packaging structure is shown in FIG. 1, which includes a chip to be packaged 200 and a cover layer 300. A micro lens 211 is formed on a first surface 200a of the chip to be packaged 200, and a contact pad 212 is formed inside the chip to be packaged 200 close to the first surface 200a. A support structure 320 is provided between the first surface 200a of the chip to be packaged 200 and a first surface 300a of the cover layer 300. An adhesive glue is coated on a surface of the support structure 320 for bonding the cover layer 300 with the chip to be packaged 200. After the chip to be packaged 200 is bonded with the cover layer 300, a cavity 310 is formed between the micro lens 211 and the cover layer 300.

In order to achieve the electrical connection between the chip to be packaged 200 and an external circuit board, multiple etching grooves 215 are formed on a second surface 200b of the chip to be packaged 200, and bottom of each of the etching grooves 215 is electrically connected to the contact pad 212. An insulation layer 213 and a conducting layer 214 are formed on a surface of the etching groove 215. A solder joint 216 is formed on the conducting layer 214, and the solder joint 216 is electrically connected to a solder joint on the external circuit board. Therefore, the chip to be packaged 200 can be electrically connected to the external circuit board.

However, it is required to perform the etching process on the chip to be packaged in the conventional wafer level packaging structure, a damage rate of the chip to be packaged is increased. Moreover, since the etching process and the thin film deposition process are to be performed for the packaging structure, the process is complex and the packaging cost is high.

### SUMMARY

In view of the above, an image sensor packaging structure is provided according to a first aspect of the present disclosure to reduce a damage rate of a chip to be packaged.

A packaging method for an image sensor packaging structure is provided according to a second aspect of the present disclosure to simplify a packaging process and reduce a packaging cost.

In order to achieve the above objects of the disclosure, the following technical solutions are adopted in the present disclosure.

An image sensor packaging structure is provided, which includes:

a chip to be packaged, where the chip to be packaged includes a first surface and a second surface respectively located on two sides of the chip to be packaged, the first surface is provided with a photosensitive region and a first contact pad located around the photosensitive region; and

a substrate provided on the side of the first surface of the chip to be packaged, where the substrate includes a third surface and a fourth surface respectively located on two sides of the substrate, the third surface is provided with a second contact pad and a third contact pad, the second contact pad is located on a side of the third contact pad facing away from the photosensitive region, the first surface of the chip to be packaged is opposite to the third surface of the substrate, and the first contact pad is connected to the third contact pad.

Optionally, the substrate may be provided with a conducting layer, where the conducting layer is electrically connected with the second contact pad and the third contact pad, the conducting layer is made of a metal wiring, and a line width and a line spacing of the metal wiring range from 20 to 50 micrometers.

Optionally, the line width and the line spacing of the metal wiring may be 30 micrometers.

Optionally, a solder bump spot may be further formed on a surface of the first contact pad and/or the third contact pad.

Optionally, the substrate may be made of a transparent material.

Optionally, the substrate may be made of an opaque material, where the substrate is provided with an opening penetrating the substrate, and the photosensitive region of the chip to be packaged is exposed through the opening.

Optionally, the fourth surface of the substrate may be provided with a protective layer covering the opening.

Optionally, a lens assembly may be provided in a position on the fourth surface of the substrate corresponding to the photosensitive region.

Optionally, the lens assembly may include a lens and a lens holder for supporting the lens.

Optionally, a height of the second contact pad may be greater than a sum of heights of the chip to be packaged, the first contact pad and the third contact pad.

A packaging method for an image sensor packaging structure is provided, which includes:

providing a chip to be packaged and a substrate, where the chip to be packaged includes a first surface and a second surface respectively located on two sides of the chip to be packaged, the first surface is provided with a photosensitive region and a first contact pad located around the photosensitive region, the substrate includes a third surface and a fourth surface respectively located on two sides of the substrate, the third surface is provided with a second contact pad and a third contact pad, and the second contact pad is located on a side of the third contact pad facing away from the photosensitive region;

arranging the chip to be packaged and the substrate, where the first surface is opposite to the third surface, and the first contact pad is aligned with the third contact pad; and

soldering the first contact pad and the third contact pad together to package the chip to be packaged and the substrate.

Optionally, the substrate may be provided with a conducting layer, where the conducting layer is electrically connected with the second contact pad and the third contact pad, the conducting layer is made of a metal wiring, and a line width and a line spacing of the metal wiring range from 20 to 50 micrometers.

Optionally, the line width and the line spacing of the metal wiring may be 30 micrometers.

Optionally, the substrate may be made of a transparent material.

Optionally, the substrate may be made of an opaque material, where the substrate is provided with an opening penetrating the substrate, and the photosensitive region of the chip to be packaged is exposed through the opening.

Optionally, the method may further include: forming a protective layer on the fourth surface of the substrate, where the protective layer covers the opening.

Optionally, the method may further include: forming a lens assembly in a position on the fourth surface of the substrate corresponding to the photosensitive region.

Compared with the conventional technology, the present disclosure has the following beneficial effects.

In the image sensor packaging structure according to the present disclosure, a signal of the chip to be packaged can be transmitted through the first contact pad, the third contact pad and the second contact pad. The second contact pad provided on the third surface of the substrate can be electrically connected with the solder joint on an external circuit board, therefore, the signal can be transmitted between the chip to be packaged and the external circuit board through the first contact pad, the third contact pad and the second contact pad. In the signal transmission mode, it is not necessary to etch a back surface of the chip to be packaged to form an etching groove extending from the back surface of the chip to be packaged to the interior of the chip to be packaged. Therefore, with a packaging structure of the wafer level image sensor according to the present disclosure, the damage rate of the chip to be packaged is reduced.

Furthermore, in the packaging method according to the present disclosure, it is only required to form the contact pads on the chip to be packaged and the substrate without performing the etching process and the thin film deposition process. Therefore, with the packaging method according to the present disclosure, the packaging process is simplified, thereby being beneficial to reduce the packaging cost.

### BRIEF DESCRIPTION OF THE DRAWINGS

In order to illustrate solutions of the present disclosure and the conventional technology more clearly, drawings to be used in the description of the technical solutions of the present disclosure and the conventional technology are briefly described below. Apparently, the drawings only illustrate some embodiments of the present disclosure, and other drawings may be obtained by those skilled in the art without any creative work.

FIG. 1 is a schematic diagram of a packaging structure of a wafer level image sensor according to the conventional technology;

FIG. 2 is a schematic diagram of a first image sensor packaging structure according to an embodiment of the present disclosure;

FIG. 3 is a schematic diagram of a second image sensor packaging structure according to an embodiment of the present disclosure;

FIG. 4 is a schematic diagram of a third image sensor packaging structure according to an embodiment of the present disclosure; and

FIG. 5 is a schematic flow chart of a packaging method for an image sensor packaging structure according to an embodiment of the present disclosure.

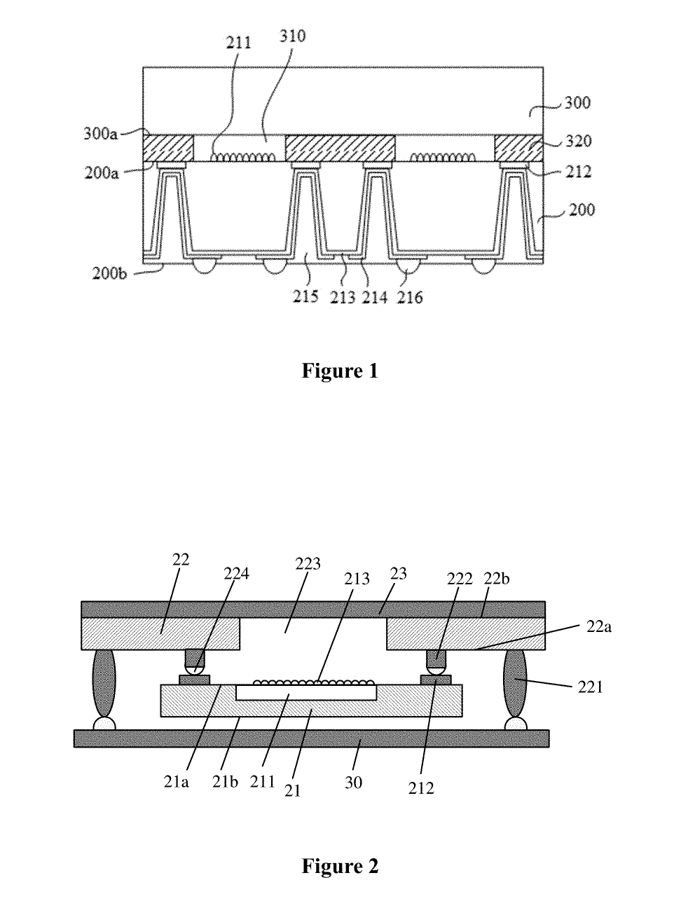

### DETAILED DESCRIPTION OF EMBODIMENTS

The specific implementation of the present disclosure is described in detail hereinafter in conjunction with the drawings.

As described in the background, in the packaging structure of a wafer level image sensor according to the conventional technology, the damage rate of the chip to be packaged is high.

In order to solve the above technical problem, an image sensor packaging structure is provided, which includes: a chip to be packaged, where the chip to be packaged includes a first surface and a second surface opposite to each other, and the first surface is provided with a photosensitive region and a first contact pad located around the photosensitive region; and

a substrate provided on a side of the first surface of the chip to be packaged, where the substrate includes a third surface and a fourth surface respectively located on two sides of the substrate, the third surface is provided with a second contact pad and a third contact pad, the second contact pad is located on a side of the third contact pad facing away from the photosensitive region, the first surface of the chip to be packaged is opposite to the third surface of the substrate, and the first contact pad is connected to the third contact pad.

In the image sensor packaging structure according to the present disclosure, the signal of the chip to be packaged can be transmitted through the first contact pad, the third contact pad and the second contact pad. The second contact pad provided on the third surface of the substrate can be electrically connected with solder joints on an external circuit board, therefore, the signal can be transmitted between the chip to be packaged and the external circuit board through the first contact pad, the third contact pad and the second contact pad. In the signal transmission mode, it is not necessary to etch a back surface of the chip to be packaged to form an etching groove extending from the back surface of the chip to be packaged to the interior of the chip to be packaged. Therefore, with the packaging structure of the wafer level image sensor according to the present disclosure, the damage rate of the chip to be packaged is reduced.

To make the above objects, features and advantages of the present disclosure more apparent and easier to be understood, specific embodiments of the present disclosure are illustrated in detail in conjunction with the drawings hereinafter. When describing the embodiments of the present disclosure, sectional views showing the structure of the device may be partially enlarged in accordance with a specific scale for ease of illustration. Moreover, the schematic diagrams are only schematic, which should not be understood as limiting the scope of protection of the present disclosure. Furthermore, three-dimensional space sizes, i.e. the length, the width and the depth should be considered in actual fabrication.

Reference is made to FIG. 2, which is a cross-sectional view of an image sensor packaging structure according to an embodiment of the present disclosure. As shown in FIG. 2, the image sensor packaging structure includes: a chip to be packaged 21 and a substrate 22.

The chip to be packaged 21 includes a first surface 21a and a second surface 21b respectively located on two sides of the chip to be packaged. The first surface 21a is provided with a photosensitive region 211 and a first contact pad 212 formed around the photosensitive region 211.

The substrate 22 is provided on a side of the first surface 21a of the chip to be packaged 21, and includes a third surface 22a and a fourth surface 22b respectively located on two sides of the substrate. The third surface 22a is provided with a second contact pad 221 and a third contact pad 222, and the second contact pad 221 is located on a side of the third contact pad 222 facing away from the photosensitive region 211. The first surface 21a of the chip to be packaged 21 is opposite to the third surface 22a of the substrate 22, and the third contact pad 222 is connected to the first contact pad 212.

It should be noted that the second contact pad 221 provided on the substrate 22 is configured to electrically connect with a circuit board 30 outside the packaging structure. Specifically, the circuit board 30 is provided with a solder joint, and the second contact pad 221 may be connected to the solder joint on the circuit board 30, thereby transmitting the electrical signal between the chip to be packaged 21 and the external circuit board 30. It should be further noted that the circuit board 30 is not the component of the image sensor packaging structure according to the present disclosure.

In the embodiment of the present disclosure, the chip to be packaged 21 is an image sensor chip, where the image sensor may be one of the complementary metal oxide semiconductor (CMOS) image sensor and the charge-coupled device (CCD) image sensor.

The photosensitive region 211 may be provided in any position on the first surface 21a of the chip to be packaged 21, and generally, the photosensitive region 211 is provided in a central region of the first surface 21a of the chip to be packaged 21.

An image sensor unit (not shown in FIG. 2) may be further formed in the photosensitive region 211 of the chip to be packaged 21, where a micro lens 213 is formed on a surface of the image sensor unit. The micro lens 213 is configured to collect incident light reaching a surface of the photosensitive region 211 and transmitting the incident light into the image sensor unit.

The first contact pad 212 is provided around the photosensitive region 211. The first contact pad 212 is made of a conducting material, which may be a metal material, such as Al, Au and Cu. Specifically, the number of the first contact pads 212 may be greater than one. The multiple first contact pads may be located on at least one side of the photosensitive region 211. As an example, the first contact pads 212 may be located on four sides of the photosensitive region 211, the first contact pads 212 are distributed in a rectangular form on the chip to be packaged 21, and several first contact pads 212 are provided on each side. It should be noted that the number of the first contact pads 212 depends on the type of the chip to be packaged. In another example, the first contact pads 212 are located on two sides of the photosensitive region 211 opposite to each other. It should be noted that, since the first contact pads 212 may be distributed in different shapes based on the different types of the chip, the distribution position of the first contact pad 212 does not limit the scope of protection of the present disclosure.

It should be noted that, in the embodiment of the present disclosure, as a whole chip to be packaged, the chip to be packaged 21 is not only provided with the above photosensitive region 211 and the first contact pad 212 located around the photosensitive region 211, but also provided with a drive unit (not shown in FIG. 2) for driving the chip, a reading unit (not shown in FIG. 2) for acquiring a current of the photosensitive region, and a processing unit (not shown in FIG. 2) for processing the current of the photosensitive region. In addition, other components may be further provided on the chip to be packaged 21. Since the components are not closely related to the inventive concepts of the present disclosure, they are not described in detail herein.

In the embodiment of the present disclosure, the substrate 22 may be made of a transparent material or an opaque material. The material of the substrate 22 may be the same as the material of the circuit board 30. For example, the substrate 22 may be made of plastic or copper. Furthermore, the substrate 22 may be made of glass. In order to make the light reach the photosensitive region 211 of the chip to be packaged, in a case where the substrate 22 is made of an opaque material, the substrate 22 is provided with an opening 223 penetrating both surfaces of the substrate 22, as shown in FIG. 2. The photosensitive region 211 of the chip to be packaged 21 can be exposed through the opening 223. As a specific embodiment of the present disclosure, a position of the opening 223 may correspond to a position of the photosensitive region 211. Moreover, the size of the opening 223 may be larger than or equal to the size of the photosensitive region 211. Through the opening 223, the light may directly irradiate the surface of the photosensitive region 211. In this embodiment, the third contact pad 222 may be located around the opening 223, and the second contact pad 221 is located on a side of the third contact pad 222 facing away from the photosensitive region 211.

In order to realize an electrical connection between the circuit on the chip to be packaged 21 and a peripheral circuit, the substrate 22 is provided with a conducting layer (not shown in FIG. 2). The conducting layer may be made of a metal wiring. In order to reduce the size of the image sensor packaging structure, in the embodiment of the present disclosure, a line width and a line spacing of the metal wiring on the substrate 22 are small, for example, ranging from 20 to 50 micrometers. More specifically, the line width and the line spacing of the metal wiring on the substrate 22 are 30 micrometers. Compared with the line width and the line spacing of about 100 micrometers according to the conventional technology, the size of the image sensor packaging structure according to the present disclosure is reduced by about two-thirds than that of the packaging structure in the conventional technology. Therefore, with the image sensor packaging structure according to the present disclosure, the produced device is further miniaturized.

It should be noted that, the size of the substrate 22 is generally larger than the size of the chip to be packaged 21, and in the image sensor packaging structure according to the embodiment of the present disclosure, the second contact pad 221 is located in an outer position relative to the chip to be packaged 21. Therefore, after the second contact pad 221 and the circuit board 30 are connected together, the chip to be packaged 21 is packaged between the circuit board 30 and the substrate 22, i.e., the chip to be packaged is packaged between the substrate 22 and the circuit board 30. Therefore, the substrate 22 and the circuit board 30 can protect the chip to be packaged, thereby preventing the chip to be packaged 21 from cracking.

As an example, the second contact pad 221 may be a metal solder ball. The second contact pad 221 may be made of a conventional metal welding material in the art, such as tin. It should be noted that, there may be multiple second contact pads 221, which may be distributed in a regular form or distributed on two parallel lines on the substrate 22.

In the embodiment of the present disclosure, the third contact pad 222 may be a metal bump block, and the metal may be Al, Au or Cu. It should be noted that the position of the third contact pad 222 on the substrate corresponds to the position of the first contact pad 212 on the chip to be packaged. In a case where the first contact pads 212 are distributed in a rectangular form on the chip to be packaged 21, the third contact pads 222 are also distributed in a rectangular form on the substrate 22. Moreover, the number of the third contact pads 222 is the same as the number of the first contact pads 212.

It should be noted that, in order to realize the soldering between the third contact pad 222 and the first contact pad 212 on the chip to be packaged 21, a solder bump spot 224 may be formed on the surface of the third contact pad 222. The solder bump spot 224 is configured to bond with the first contact pad 212, thereby soldering the first contact pad 212 and the second contact pad 222 together, and thus packaging the substrate 22 and the chip to be packaged 21.

In the embodiment of the present disclosure, the material of the solder bump spot 224 is related to the material of the first contact pad 212 and a joining process of the solder bump spot 224 and the first contact pad 212. In a case where the first contact pad 212 is made of Al, the solder bump spot 224 is made of Au and the joining process is the ultrasonic thermocompression method. In a case where the first contact pad 212 is made of Au, the solder bump spot 224 is made of Sn and the joining process is the eutectic bonding method.

As a variation of the embodiment of the present disclosure, the solder bump spot may be formed on the surface of the first contact pad 212. In this case, the surface of the third contact pad 222 may be provided with no solder bump spot, and the first contact pad 212 and the third contact pad 222 are soldered together via the solder bump spot formed on the surface of the first contact pad 212. The material of the solder bump spot formed on the surface of the first contact pad 212 is related to the material of the third contact pad 222 and a joining process of the solder bump point and the third contact pad. In a case where the third contact pad 222 is made of Al, the solder bump spot 224 is made of Au and the joining process is the ultrasonic thermocompression method. In a case where the third contact pad 222 is made of Au, the solder bump spot 224 is made of Sn and the joining process is the eutectic bonding method.

In the embodiment of the present disclosure, the circuit board 30 may be a rigid printed circuit board (PCB) or a flexible printed circuit board (FPC). It should be noted that, the circuit board 30 is provided with multiple solder joints, the second contact pad 221 provided on the substrate 22 is connected to the solder joint on the circuit board 30, thereby connecting the chip to be packaged 21 and the substrate 22 which are packaged to the circuit board 30.

It should be noted that, in the image sensor packaging structure, the electrical signal is transmitted between the chip to be packaged 21 and the circuit board 30 through the first contact pad 212, the solder bump spot 224, the third contact pad 222, the conducting layer and the second contact pad 221. In the signal transmission mode, it is not necessary to etch a back surface of the chip to be packaged to form an etching groove extending from the back surface of the chip to be packaged to the interior of the chip to be packaged. Therefore, with the packaging structure of the wafer level image sensor according to the present disclosure, the damage rate of the chip to be packaged is reduced.

In the embodiment of the present disclosure, the first contact pad 212 provided on the chip to be packaged 21 is generally a contact pad protruding from the first surface 21a, and the third contact pad 222 provided on the substrate 22 is a contact pad protruding from the third surface 22a. In addition, in order to enable the circuit board 30 to protect the second surface of the chip to be packaged 21, a distance between the circuit board 30 and the substrate 22 should not be less than a sum of heights of the first contact pad 212, the third contact pad 222, the chip to be packaged 21 and the solder joint on the circuit board 30. Therefore, in the embodiment of the present disclosure, a sum of the heights of the second contact pad 221 and the solder joint on the circuit board 30 is not less than the sum of the heights of the chip to be packaged 21, the first contact pad 212 and the third contact pad 222. Moreover, a difference between the height of the second contact pad 221 and the sum of the heights of the chip to be packaged 21, the first contact pad 212 and the third contact pad 222 is not less than 100 micrometers.

As an optional embodiment of the present disclosure, in order to prevent the photosensitive region from being contaminated by the external environment, as shown in FIG. 2, the fourth surface of the substrate 22 is further provided with a protective layer 23 for protecting the photosensitive region 211. The protective layer 23 may be a plastic thin film layer or a glass layer. It should be noted that, in a case where the substrate 22 is provided with the opening 233, the protective layer 23 further covers a surface region of the opening 223.

It should be noted that, in a case where the protective layer 23 is made of a transparent material, the lens assembly may be assembled on the protective layer 23 directly, or may be assembled on the fourth surface of the substrate 22 after the protective layer 23 is removed. In a case where the protective layer 23 is made of an opaque material, it is required to remove the opaque material layer before the lens assembly is assembled subsequently, and the lens assembly is assembled in a position on the fourth surface of the substrate 22 corresponding to the photosensitive region.

Furthermore, it should be noted that, in a case where no protective layer 23 is covered above the opening 223, the optical phenomena such as chromatic aberration or a ghost image may not appear in the formed image sensor. Therefore, when assembling the lens assembly subsequently, it is better to remove the protective layer or the glass layer, thereby being beneficial to improve the image quality of the image sensor.

It should be noted that, in the image sensor packaging structure shown in FIG. 2, the substrate 22 is an opaque substrate. As another embodiment of the present disclosure, the substrate 22 may also be a transparent substrate, such as a glass substrate. In a case where the substrate 22 is the transparent substrate, the substrate may be provided with no opening since the light may reach the photosensitive region 211 through the transparent substrate. The schematic diagram of the image sensor packaging structure is illustrated as FIG. 3.

The image sensor packaging structure shown in FIG. 3 is substantially the same as the image sensor packaging structure shown in FIG. 2, and differs from the image packaging structure shown in FIG. 2 only in that: the substrate 22′ shown in FIG. 3 is a transparent substrate, and no opening corresponding to the photosensitive region 211 is provided on the substrate 22′. In FIG. 3, 22′a and 22′b respectively represent a third surface and a fourth surface of the substrate 22′. 221′ represents a second contact pad provided on the third surface of the substrate 22′, 222′ represents a third contact pad provided on the third surface of the substrate 22′, and 224′ represents a solder bump spot provided on the third contact pad 222′.

It should be noted that, as an extension of the embodiment of the present disclosure, the transparent substrate may also be provided with the opening. In this case, the image sensor packaging structure is the same as the packaging structure shown in FIG. 2.

It should be noted that, in the image sensor packaging structures shown in FIGS. 2 and 3, the fourth surface of the substrate 22 is provided with no lens assembly. In order to produce the image device, it is required to mount the lens assembly in the position on the fourth surface of the substrate 22 corresponding to the photosensitive region in the production of the image device.

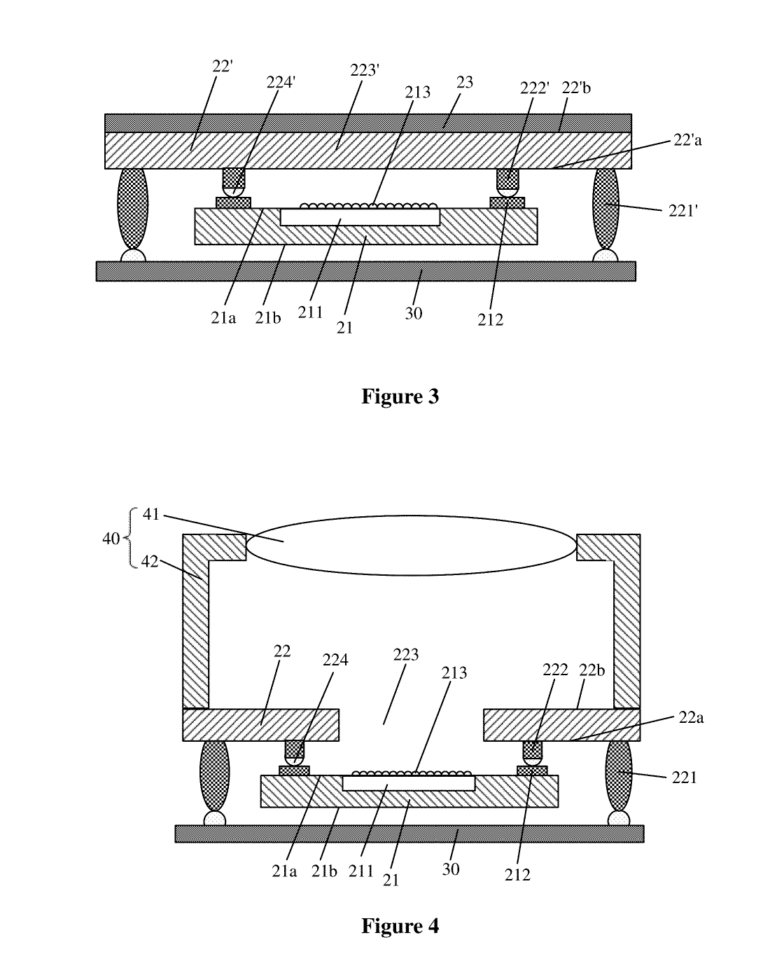

As another embodiment of the present disclosure, in the image sensor packaging structures shown in FIG. 2 and FIG. 3, the lens assembly may be further provided in the position on the fourth surface of the substrate corresponding to the photosensitive region, thereby eliminating the subsequent process of assembling the lens assembly, as shown in FIG. 4.

It should be noted that, FIG. 4 shows an image sensor packaging structure improved based on the image sensor packaging structure shown in FIG. 2, and there are multiple similarities between the image sensor packaging structure shown in FIG. 4 and the image sensor packaging structure shown in FIG. 2. For the sake of brevity, only the difference is emphasized herein and the similarity may be seen in the related description of FIG. 2.

The image sensor packaging structure shown in FIG. 4 not only includes components shown in FIG. 2, but also includes:

a lens assembly 40 provided in a position on the fourth surface of the substrate 22 corresponding to the photosensitive region. The lens assembly 40 includes a lens 41 and a lens holder 42 for supporting the lens 41. Specifically, a position of the lens 41 corresponds to the position of the opening 223, and a size of the lens 41 is larger than or equal to the size of the opening 223, so that the external light can reach a surface of the photosensitive region 211 of the image sensor through the lens. In a case where the substrate 22 is a transparent substrate and is provided with no opening, the size of the lens 41 is larger than or equal to the size of the photosensitive region 211.

It should be noted that, the image sensor packaging structure shown in FIG. 4 does not include the protective layer 23 shown in FIG. 2. As an extension of the embodiment of the present disclosure, in a case where the protective layer provided on the fourth surface of the substrate is made of a transparent material, the lens assembly 40 may also be provided on the protective layer directly, which is not described in detail herein.

In other embodiment, the fourth surface of the substrate 22 may be further provided with other devices, such as a resistor, an inductor, a capacitor, an integrated circuit block or an optical component. The type of the device may be selected based on the type of the substrate and the chip to be packaged.

Furthermore, in a case where the size of the lens 41 is larger than the size of the opening, there is a certain transverse distance between the lens holder 42 and the opening edge, and there is a certain vertical distance between the substrate 22 and the lens 41. Therefore, other devices may be provided on the fourth surface of the substrate 22 between the lens holder 42 and the substrate 22, and may form a stacking structure with a high density between the lens holder 42 and the substrate 22, thereby facilitating the miniaturization of devices. Furthermore, an optical assembly, such as a polarizer and an infrared filter, may be further provided between the lens 41 and the opening 223, thereby improving the imaging quality of the image sensor.

The specific embodiments of the image sensor packaging structure according to the embodiment of the present disclosure are described above.

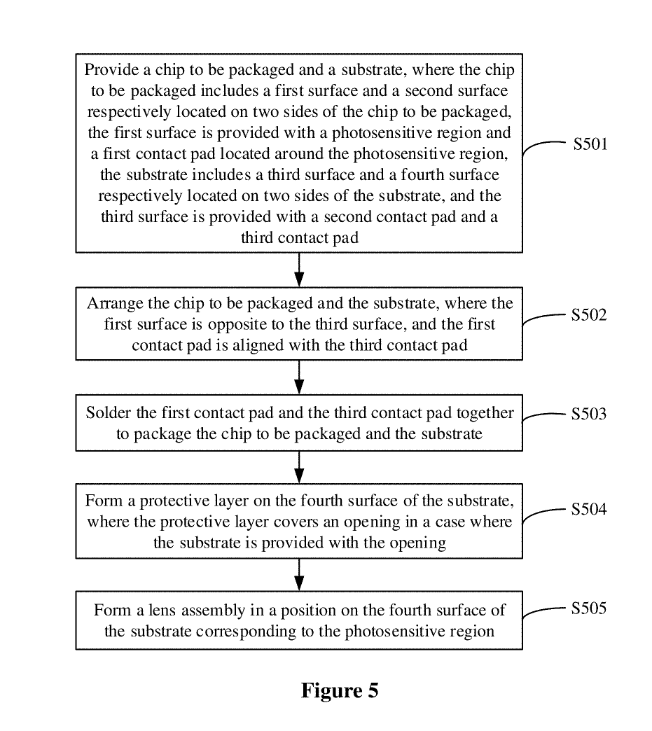

Based on the image sensor packaging structure provided according to the embodiment of the present disclosure, correspondingly, a packaging method for the image sensor packaging structure is further provided according to an embodiment of the present disclosure, as shown in FIG. 5.

FIG. 5 is a schematic flow chart of a packaging method for an image sensor packaging structure according to the embodiment of the present disclosure. As shown in FIG. 5, the packaging method includes the following steps S501 to S505.

In S501, a chip to be packaged and a substrate are provided. The chip to be packaged includes a first surface and a second surface respectively located on two sides of the chip to be packaged, and the first surface is provided with a photosensitive region and a first contact pad located around the photosensitive region. The substrate includes a third surface and a fourth surface respectively located on two sides of the substrate, the third surface is provided with a second contact pad and a third contact pad, and the second contact pad is located on a side of the third contact pad facing away from the photosensitive region.

As shown in FIG. 2, the chip to be packaged 21 includes a first surface 21a and a second surface 21b opposite to each other. The first surface is provided with a photosensitive region 211 and a first contact pad 212 located around the photosensitive region 211. An image sensor unit (not shown in FIG. 2) is provided in the photosensitive region 211, where a micro lens 213 is formed on a surface of the image sensor unit. The micro lens 213 is configured to collect incident light reaching a surface of the photosensitive region 110 and transmit the incident light into the image sensor unit.

As shown in FIG. 2, the substrate 22 includes a third surface 22a and a fourth surface 22b respectively located on two sides of the substrate 22, where the third surface 22a is provided with a second contact pad 221 and a third contact pad 223. The substrate 22 may be made of a transparent material or an opaque material. In a case where the substrate 22 is made of an opaque material, the substrate 22 is provided with an opening 223 penetrating the third surfaces 22a and the fourth surface 22b of the substrate 22 in order to enable the light to irradiate the photosensitive region of the chip to be packaged. The photosensitive region of the chip to be packaged which is packaged can be exposed through the opening 223.

In order to realize the electrical connection between the second contact pad 221 and the third contact pad 230, the substrate is provided with a conducting layer. The conducting layer is made of a metal wiring. A line width and a line spacing of the metal wiring range from 20 to 50 micrometers. Furthermore, the line width and the line spacing of the metal wiring are 30 micrometers.

In step S502, the chip to be packaged and the substrate are arranged, such that the first surface is opposite to the third surface, and the first contact pad is aligned with the third contact pad.

It should be noted that, in order to align the first contact pad with the third contact pad easily, the substrate 22 may be provided with an alignment mark. Specifically, the alignment mark may be a position mark of the chip to be packaged formed on the third surface 22a. In addition, a shape of the position mark of the chip to be packaged is similar to the shape of the chip to be packaged, and a size of the position mark is equal to or slightly larger than the size of the chip to be packaged. For example, in a case where the shape of the chip to be packaged is square, the shape of the position mark of the chip to be packaged formed on the substrate 22 is also square.

After the chip to be packaged 21 is arranged in a position indicated by the position mark of the chip to be packaged on the substrate 22, the first contact pad 212 and the third contact pad 222 are aligned automatically.

As an extension of the embodiment of the present disclosure, cooperating alignment marks may be formed on the chip to be packaged and the substrate. In a case where the alignment mark on the chip to be packaged is aligned with the alignment mark on the substrate in a cooperating manner, the first contact pad 212 is aligned with the third contact pad 222.

In step S503, the first contact pad and the third contact pad are soldered together to package the chip to be packaged and the substrate.

The first contact pad 212 is soldered with the third contact pad 222 together via the solder bump spot 224 formed on the surface of the first contact pad 212 or the third contact pad 222. The soldering mode includes the eutectic bonding, the ultrasonic thermocompression, the thermocompression bonding and the ultrasonic bonding, etc.

By performing the above steps, the image sensor packaging structure according to the embodiment of the present disclosure may be formed. Since it is only required to form the contact pads on the chip to be packaged and the substrate according to the packaging method provided in the present disclosure without performing the etching process and the thin film deposition process, the packaging process is simplified with the packaging method according to the present disclosure, thereby being beneficial to reduce the packaging cost.

Furthermore, in order to realize the electrical connection between the packaging structure and the circuit board, the second contact pad on the packaged substrate may be soldered onto the circuit board. It should be noted that, the circuit board according to the embodiment of the present disclosure may be the conventional circuit board in the art, and the circuit board may be a rigid printed circuit board or a flexible printed circuit board.

In order to prevent the photosensitive region of the formed image sensor packaging structure from being contaminated by the external environment, as an optional embodiment of the present disclosure, the above packaging method may include following steps.

In step S504, a protective layer is formed on the fourth surface of the substrate. The protective layer covers an opening in a case where the substrate is provided with the opening.

Specifically, as shown in FIG. 2, a protective layer 23 is formed on the fourth surface 22b of the substrate 22. In a case where the substrate is provided with an opening, the protective layer covers the opening. It should be noted that the protective layer 23 may be a plastic thin film layer or a glass layer.

It should be noted that, the performing time of step 504 is not limited in the embodiment of the present disclosure. Step 504 may be performed before the chip to be packaged 21 and the substrate 22 are packaged, or may be performed after the chip to be packaged 21 and the substrate 22 are packaged. As an example, step S504 is performed after the chip to be packaged 21 and the substrate 22 are packaged in the embodiment of the present disclosure.

Furthermore, as another embodiment of the present disclosure, the above packaging method may further include the following step such that the formed packaging structure includes a lens assembly.

In step S505, the lens assembly is formed in a position on the fourth surface of the substrate corresponding to the photosensitive region.

As shown in FIG. 4, the lens assembly 40 is formed in the position on the fourth surface 22b of the substrate 22 corresponding to the photosensitive region. The lens assembly 40 includes a lens 41 and a lens holder 42 for supporting the lens 41. A position of the lens 41 corresponds to the position of the opening 223, and a size of the lens 41 is larger than or equal to the size of the opening 223, so that the external light can irradiate a surface of the photosensitive region 211 of the image sensor through the lens. In a case where the substrate 22 is a transparent substrate and is provided with no opening, the size of the lens 41 is larger than or equal to the size of the photosensitive region 211.

Those described above are only preferred embodiments of the present disclosure. It should be noted that, for those skilled in the art, improvements and modifications may also be made without departing from the principle of the present disclosure. Those improvements and modifications should also be included in the scope of protection of the present disclosure.

1. An image sensor packaging structure, comprising:
a chip to be packaged, wherein the chip to be packaged comprises a first surface and a second surface respectively located on two sides of the chip to be packaged, and the first surface is provided with a photosensitive region and a first contact pad located around the photosensitive region; and
a substrate provided on the side of the first surface of the chip to be packaged, wherein the substrate comprises a third surface and a fourth surface respectively located on two sides of the substrate, the third surface is provided with a second contact pad and a third contact pad, the second contact pad is located on a side of the third contact pad facing away from the photosensitive region, the first surface of the chip to be packaged is opposite to the third surface of the substrate, and the first contact pad is connected to the third contact pad.

2. The packaging structure according to claim 1, wherein the substrate is provided with a conducting layer, the conducting layer is electrically connected with the second contact pad and the third contact pad, the conducting layer is made of a metal wiring, and a line width and a line spacing of the metal wiring range from 20 to 50 micrometers.

3. The packaging structure according to claim 2, wherein the line width and the line spacing of the metal wiring are 30 micrometers.

4. The packaging structure according to claim 1, wherein a solder bump spot is further formed on a surface of the first contact pad and/or the third contact pad.

5. The packaging structure according to claim 1, wherein the substrate is made of a transparent material.

6. The packaging structure according to claim 1, wherein the substrate is made of an opaque material, the substrate is provided with an opening penetrating the substrate, and the photosensitive region of the chip to be packaged is exposed through the opening.

7. The packaging structure according to claim 6, wherein the fourth surface of the substrate is provided with a protective layer covering the opening.

8. The packaging structure according to claim 1, wherein a lens assembly is provided in a position on the fourth surface of the substrate corresponding to the photosensitive region.

9. The packaging structure according to claim 8, wherein the lens assembly comprises a lens and a lens holder for supporting the lens.

10. The packaging structure according to claim 1, wherein a height of the second contact pad is greater than a sum of heights of the chip to be packaged, the first contact pad and the third contact pad.

11. A packaging method for an image sensor packaging structure, comprising:
providing a chip to be packaged and a substrate, wherein the chip to be packaged comprises a first surface and a second surface respectively located on two sides of the chip to be packaged, the first surface is provided with a photosensitive region and a first contact pad located around the photosensitive region, the substrate comprises a third surface and a fourth surface respectively located on two sides of the substrate, the third surface is provided with a second contact pad and a third contact pad, and the second contact pad is located on a side of the third contact pad facing away from the photosensitive region;
arranging the chip to be packaged and the substrate, wherein the first surface is opposite to the third surface and the first contact pad is aligned with the third contact pad; and
soldering the first contact pad and the third contact pad together to package the chip to be packaged and the substrate.

12. The method according to claim 11, wherein the substrate is provided with a conducting layer, the conducting layer is electrically connected with the second contact pad and the third contact pad, the conducting layer is made of a metal wiring, and a line width and a line spacing of the metal wiring range from 20 to 50 micrometers.

13. The method according to claim 12, wherein the line width and the line spacing of the metal wiring are 30 micrometers.

14. The method according to claim 11, wherein the substrate is made of a transparent material.

15. The method according to claim 11, wherein the substrate is made of an opaque material, the substrate is provided with an opening penetrating the substrate, and the photosensitive region of the chip to be packaged is exposed through the opening.

16. The method according to claim 15, further comprising:
forming a protective layer on the fourth surface of the substrate, wherein the protective layer covers the opening.

17. The method according to claim 11, further comprising:
forming a lens assembly in a position on the fourth surface of the substrate corresponding to the photosensitive region.

18. The packaging structure according to claim 2, wherein a lens assembly is provided in a position on the fourth surface of the substrate corresponding to the photosensitive region.

19. The packaging structure according to claim 2, wherein a height of the second contact pad is greater than a sum of heights of the chip to be packaged, the first contact pad and the third contact pad.

20. The method according to claim 12, further comprising:
forming a lens assembly in a position on the fourth surface of the substrate corresponding to the photosensitive region.
